(19) United States
(12) Patent Application Publication
(10) Pub. No.: US 2015/0118603 A1
(43) Pub. Date: Apr. 30, 2015

(54) PHOTO MASK AND METHOD OF MANUFACTURING THE SAME, AND METHOD OF FORMING TRENCHES BY USING PHOTO MASK

(71) Applicant: SAMSUNG ELECTRO-MECHANICS CO., LTD., Gyeonggi-Do (KR)

(72) Inventors: Dae Jo HONG, Hwasung-si (KR); Oh Hi LEE, Busan (KR); Soon Jin CHO, Cheongju-si (KR)

(73) Assignee: SAMSUNG ELECTRO-MECHANICS CO., LTD., Gyeonggi-Do (KR)

(21) Appl. No.: 14/224,112

(22) Filed: Mar. 25, 2014

(30) Foreign Application Priority Data
Oct. 31, 2013 (KR) 10-2013-0131273

(51) Int. Cl. G03F 1/00; G03F 7/30

(52) U.S. Cl. CPC G03F 1/00; G03F 7/30
USPC 430/5; 430/325

(57) ABSTRACT

Embodiments of the invention provide a photo mask capable of simultaneously forming trenches for preventing an under-fill leakage in a process of forming an opening of a solder resist. In accordance with at least one embodiment, the photo mask includes a transparent base material having a non-transmitting film formed on one surface thereof, a semi-transmitting region formed by performing selective etching using a laser on the transparent base material, a transmitting region and a non-transmitting region formed on the transparent base material together with the semi-transmitting region, and an opening of a solder resist and trenches for preventing a leakage of an under-fill liquid or EMC mold may be simultaneously formed using the photo mask.

### CROSS REFERENCE TO RELATED APPLICATION

This application claims the benefit of and priority under 35 U.S.C. §119 to Korean Patent Application No. KR 10-2013-0131273, entitled, “Photo Mask and Method of Manufacturing the same, and Method of Forming Trenches by Using Photo Mask,” filed on Oct. 31, 2013, which is hereby incorporated by reference in its entirety into this application.

### BACKGROUND

1. Field of the Invention

The present invention relates to a photo mask and a method of manufacturing the same, and a method of forming trenches by using the photo mask.

2. Description of the Related Art

In accordance with high functionalization and miniaturization of electronic components, a technical change in which associated parts also become thin and small has been demanded. Even in parts of a printed circuit board, a thickness of the board gradually becomes thin and small. Therefore, a semiconductor chip attached to the board and a size ratio of the board have been decreased, and demands for functions in which the parts having functionality are mounted on a region other than a region having the chip attached thereto or are connected to other boards have also been continuously increased. Therefore, a technology mounting the semiconductor chip on the board has been developed from an existing bonding scheme to a flip-chip scheme, for example, as taught in U.S. Patent Publication No. 2011-0115083.

Comparing the flip-chip scheme with the existing bonding scheme, the flip-chip scheme has higher electrical performance due to higher packaging density, shorter lead, and lower inductance. However, in order to handle several defects (e.g., warpage, delamination, and the like of the board) caused by thermal expansion mismatch between the semiconductor chip and an organic board structure, an under-fill process of an epoxy for decreasing stress by heat has required, and in order to prevent an under-fill liquid from flowing to other portions of the board, it has been required that a trench is formed on the board using a laser. In addition, in order to prevent a molding (EMC) material from being intruded into a region of a solder ball pad outside a molding region in an EMC molding process for protecting the semiconductor chip mounted on the board, the trench may also be required.

In general, in a case of machining a trench for under-fill leakage prevention, a separate and additional process is required. Therefore, after a process forming an opening part of a solder resist, the trench for under-fill leakage prevention is formed using a laser. In this process, when the trench is not formed at an accurate position, a matching problem between prior and subsequent processes is caused. In order to prevent this problem, the process forming the trench using a laser, which is a subsequent process, is required to have a very high degree of precision.

### SUMMARY

Accordingly, embodiments of the present invention are provided to solve problems caused when forming trenches for preventing an under-fill leakage according to the related art.

Embodiments of the present invention provide a photo mask for collectively forming an opening for mounting a chip and trenches for preventing an under-fill leakage during an exposure process of a solder resist, and a method of forming the trenches by using the photomask.

According to an embodiment of the present invention, there is provided a photo mask capable of simultaneously forming trenches for preventing an under-fill leakage in a process of forming an opening of a solder resist. The photo mask includes a transparent base material having a non-transmitting film formed on one surface thereof, a semi-transmitting region formed by performing selective etching using a laser on the transparent base material, and a transmitting region and a non-transmitting region formed on the transparent base material together with the semi-transmitting region.

In accordance with an embodiment of the present invention, the transparent base material is a transparent film and a transparent substrate.

In accordance with an embodiment of the present invention, the non-transmitting region of the photo mask is a chrome film having a thickness of 0.1 to 0.5 m and the semi-transmitting region has different light transmissivity depending on each semi-transmitting region and a position of one semi-transmitting region. In accordance with an embodiment of the present invention, the semi-transmitting region has light transmissivity of 40% to 90% and the selective etching is performed by etching using laser of a direction imaging method.

According to another exemplary embodiment of the present invention, there is provided a method of manufacturing a photo mask, the method including forming an non-transmitting film on one surface of a transparent base materia, forming a transmitting region by etching the non-transmitting film using a laser on some regions of the base material having the non-transmitting film formed thereon, and forming a semi-transmitting region by selective etching using a laser on a portion of the non-transmitting region left on the transparent base material.

In accordance with an embodiment of the present invention, the etching using a laser is performed by an electron beam (E-BEAM) and a degree of etching is adjusted so that the semi-transmitting region has different light transmissivity at the time of selective etching using a laser.

According to another embodiment of the present invention, there is provided a method of forming trenches, the method including in forming an opening of a solder resist, preparing a photo mask having a semi-transmitting region, exposing to UV using the photo mask, and developing the solder resist after removing the photo mask.

In the trenches for preventing the under-fill leakage, according to an embodiment of the present invention, a trench in a direction opposite to an injection direction of an under-fill is formed to have a deeper depth.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view of a photo mask having a semi-transmitting region manufactured in accordance with an embodiment of the invention.

FIGS. 2A to 2C are cross-sectional views for describing a method of manufacturing the photo mask, in accordance with an embodiment of the invention. In particular, FIG. 2A is a cross-sectional view showing a process performing etching using a laser for a transmitting region in a state in which a non-transmitting film is formed on a transparent base material, FIG. 2B is a cross-sectional view showing a state in which a transmitting region is formed on the non-transmitting film left after the transmitting region is formed, by etching using a laser, and FIG. 2C is a cross-sectional view of a photo mask formed up to a semi-transmitting region having a mask pattern having a thickness thinner than the non-transmitting film after selectively etching the non-transmitting film.

FIGS. 3A to 3C are cross-sectional views for describing a method of forming a trench for preventing an under-fill leakage using the photo mask, in accordance with an embodiment of the invention. In particular, FIG. 3A is a cross-sectional view of a state in which a solder resist is applied onto a substrate, FIG. 3B is a cross-sectional view showing a process of exposing the solder resist using the photo mask through the processes of FIGS. 2A to 2C, and FIG. 3C is a cross-sectional view of a substrate in which an opening of the solder resist and a trench are formed after a development is completed.

FIGS. 4A to 4C are cross-sectional views of substrates in which several shapes of trenches are implemented, in accordance with an embodiment of the invention. In particular, FIG. 4A is a cross-sectional view of a substrate in which a V-shaped trench for preventing the under-fill leakage is formed, FIG. 4B is a cross-sectional view of a substrate in which a semicircular-shaped trench for preventing the under-fill leakage is formed, and FIG. 4C is a cross-sectional view of a substrate in which a step-shaped trench for preventing the under-fill leakage is formed.

FIG. 5 is a cross-sectional view of a printed circuit board including the trench after an EMC molding, in accordance with an embodiment of the invention.

FIG. 6 is a cross-sectional view of the printed circuit board into which an under-fill liquid is injected after mounting a chip on the board including the trench, in accordance with an embodiment of the invention.

### DETAILED DESCRIPTION

The present invention will now be described more fully hereinafter with reference to the accompanying drawings, which illustrate embodiments of the invention. This invention may, however, be embodied in many different forms and should not be construed as limited to the illustrated embodiments set forth herein. Rather, these embodiments are provided so that this disclosure will be thorough and complete, and will fully convey the scope of the invention to those skilled in the art. Like numbers refer to like elements throughout. Prime notation, if used, indicates similar elements in alternative embodiments.

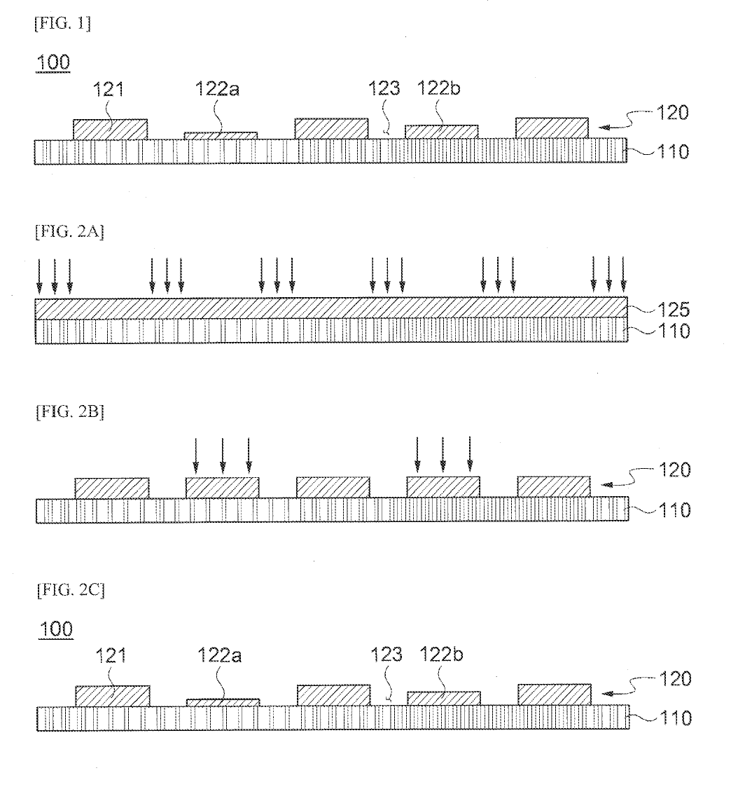

FIG. 1 is a cross-sectional view of a photo mask having a semi-transmitting region manufactured in accordance with an embodiment of the invention.

Referring to FIG. 1, photo mask 100 according to an exemplary embodiment of the present invention may include a transparent base material 110, and a mask pattern layer 120 having a non-transmitting region 121, semi-transmitting regions 122a and 122b, and a transmitting region 123 formed on the transparent base material.

In accordance with an embodiment of the invention, the transparent base material 110 is a transparent glass substrate and a transparent film. However, a material of the transparent base material is not limited in the present exemplary embodiment invention.

As further shown in FIG. 1, a mask pattern layer 120, in accordance with an embodiment of the invention, is classified into the non-transmitting region 121 in which light is completely blocked, the semi-transmitting regions 122a and 122b in which the light is partially blocked, and the transmitting region 123 in which the light is permeated as it is.

In accordance with an embodiment of the invention, the non-transmitting region 121, which is a region in which a non-transmitting film 125 formed on the transparent base material 110 is not etched and maintains a thickness of a laminated state, is a region in which the light including ultraviolet (UV) is hardly permeated. Therefore, in an exposure process which will be performed later, a solder resist region corresponding to the non-transmitting region 121 is not cured by the UV, such that it may be completely removed by a development liquid during development.

In addition, the semi-transmitting region 122a and 122b, in accordance with an embodiment of the invention, is formed by etching a chrome film of the non-transmitting region by a selective etching using laser to thereby adjust a thickness thereof.

In a case of a photo mask using a semi-transmitting film (or a semi-light transmitting film) according to the related art, a technology of arranging and forming a light shielding pattern having a pattern dimension of a resolution limit or less of an exposure machine using the mask is generally known, but according to an exemplary embodiment of the invention, the semi-transmitting region is implemented by decreasing the thickness of the chrome film which is used as the mask, by etching using a laser. In this case, the thickness is adjusted by a method of decreasing an etching time as compared to the case of etching the transmitting region 123, a method of decreasing energy at the time of etching, or a method using both the above mentioned methods.

Thereby, in accordance with an exemplary embodiment, there is provided an inventive step of an invention as compared to the related art in that light transmissivity for the semi-transmitting region is freely adjusted by adjusting the thickness of the semi-transmitting film configuring the semi-transmitting regions 122a and 122b. In this case, the light transmissivity of the semi-transmitting region is adjusted depending on a depth of the trench, and the semi-transmitting region has a light transmissivity of 40% to 90%. When the semi-transmitting region has light transmissivity which is below 40%, the solder resist is not sufficiently cured, such that all of the solder resist is removed during the development process. Therefore, this is not suitable. When the semi-transmitting region has light transmissivity of 90% or more, a degree of cure of the solder resist is increased, such that the depth of the trench is not sufficiently formed, thereby degrading efficiency of the trench.

As a result, only a portion of UV, which is irradiated passes through the photo mask in the semi-transmitting regions 122a and 122b, such that an incomplete cure results at the solder resist region corresponding to the semi-transmitting regions 122a and 122b, and only a portion of the solder resist, which is incompletely cured, is partially removed in the development process, which is a subsequent process.

On the contrary, the transmitting region 123, which is a region completely removing the non-transmitting film 125 on the transparent base material, is a region in which all the irradiated light is transmitted. Therefore, the solder resist region corresponding to the transmitting region 123 is completely cured by UV, such that the cured solder resist is not removed in the subsequent development process.

A specific method of manufacturing the photo mask having the configuration described above will be described in more detail with reference to FIGS. 2A to 2C.

FIGS. 2A to 2C are cross-sectional views showing a method of manufacturing the photo mask 100, in accordance with an embodiment of the invention.

FIG. 2A is a cross-sectional view of a laminate in which the non-transmitting film is formed on the transparent base material. As shown, in the present exemplary embodiment, the laminate is prepared by depositing the non-transmitting film 125 on one surface of the transparent base material 110. In this case, as the non-transmitting film 125, for example, a chrome material is mainly used, and molybdenum silicide, for example, is used. However, a material of the non-transmitting film is not limited in the present exemplary embodiment invention.

In accordance with an embodiment of the invention, the non-transmitting film is implemented to have a thickness of 0.1 to 0.5 μm and advantageously has a thickness of 0.3 μm. In the case in which the non-transmitting film 125 has the thickness which is below 0.1 μm, a portion of light is transmitted when forming the non-transmitting region for blocking the light, and in the case in which the non-transmitting film 125 has the thickness exceeding 0.5 μm, excessive time and energy is required for etching the non-transmitting film for forming the transmitting region 123 and the semi-transmitting regions 122a and 122b.

As shown in FIG. 2B, some regions of the non-transmitting film 125, in accordance with an embodiment of the invention, are etched using an electron-beam (not shown) or a laser (not shown), such that the transmitting region 123 is formed. As a method of forming the transmitting region 123, an etching method using a mask (not shown) and an etching method using a laser of a direct-imaging method are used. In this case, in the etching method using the mask, a resist is deposited on the non-transmitting film 125 by a general lithography method, a resist pattern is implemented, and an etching is then performed, and in a case of laser etching of the direct-imaging method, the transmitting region 123 is formed by a method of directly removing the non-transmitting film corresponding to the transmitting region portion using a laser without using a separate resist.

In this case, regions other than the transmitting region 123 are configured of the non-transmitting region 121 in which the non-transmitting film 125 is not removed, and the semi-transmitting regions 122a and 122b having different thicknesses. Of course, the semi-transmitting regions 122a and 122b may have the same thickness.

FIG. 2C is a cross-sectional view of the photo mask manufactured in accordance with an embodiment of the present invention, where the transmitting region 123, the non-transmitting region 121, and the semi-transmitting regions 122a and 122b, in which the non-transmitting film 125 has a thickness thinner than that of the non-transmitting region 121 by selective etching using a laser, are formed.

In the present exemplary embodiment, as a method of forming the semi-transmitting regions 122a and 122b, a method of decreasing an etching time as compared to the case of etching the transmitting region 123, a method of decreasing energy at the time of etching, or a method using both the above-mentioned methods are used. In addition, it may be appreciated that the thickness of the non-transmitting film of one semi-transmitting region 122a of the semi-transmitting regions is thinner than that of the other semi-transmitting region 122b. This thickness difference is easily formed by adjusting the etching time and energy using a laser.

According to an exemplary embodiment, the thickness of the non-transmitting film is adjusted by the above-mentioned methods, such that light transmissivity is adjusted and various regions having desired light transmissivity across an entire region of the photo mask are formed. In addition, by making the thickness of the chrome film of the semi-transmitting region uniform, depths of trenches for preventing an under-fill leakage to be formed later are the same.

Next, according to an embodiment of the invention, a pellicle film (not shown) is used as a protection layer by depositing the pellicle film on the photo mask having the pattern formed thereon, if necessary.

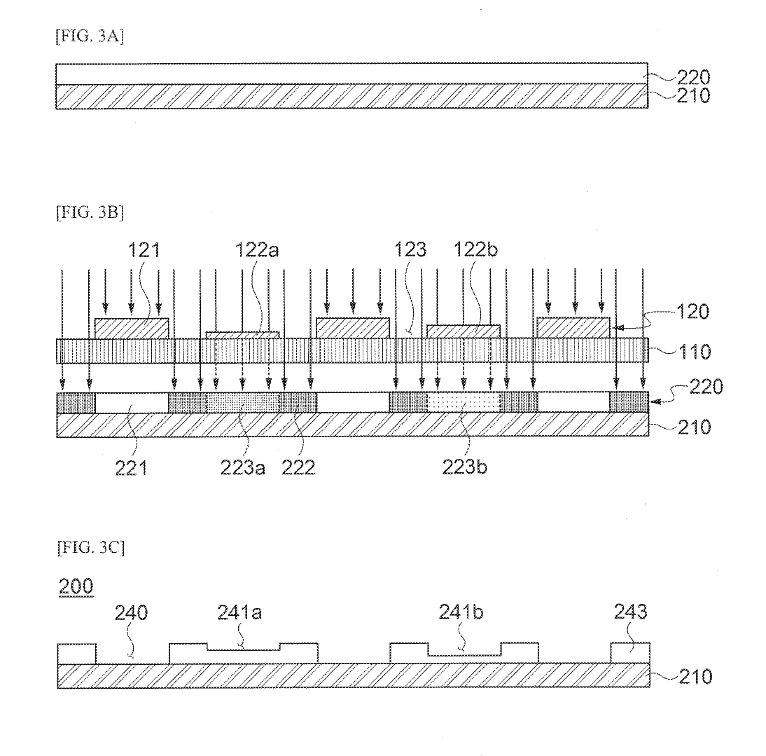

FIGS. 3A to 3C show a method of forming a trench for preventing an under-fill leakage without having an additional process using the photo mask manufactured in accordance with an embodiment of the invention during a process of forming the opening of the solder resist in the printed circuit board process.

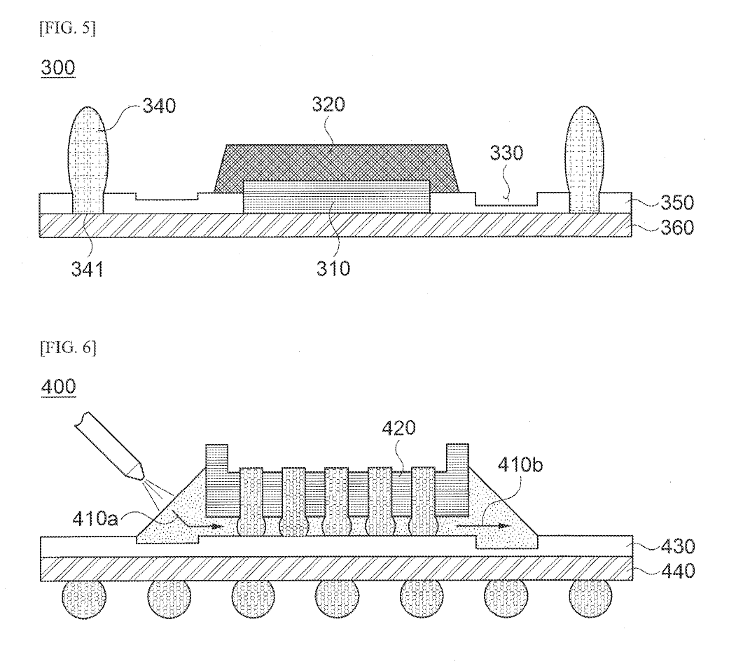

FIG. 3A is a cross-sectional view of a state in which a solder resist 220 is applied onto a substrate 210, where a process of forming an opening in a semiconductor mounted region (310 of FIG. 5) or a solder ball pad region (341 of FIG. 5) of a semiconductor package (FIG. 5) manufactured by a subsequent process is required. To this end, the opening and the trench of the solder resist applied onto the outermost layer of the substrate for manufacturing the semiconductor package are simultaneously formed by the photo mask 100.

First, as shown in FIG. 3A, a substrate 210 on which a solder resist 220 is laminated is prepared.

Next, FIG. 3B shows a process of irradiating UV on the substrate (FIG. 3A) onto which the solder resist is applied using the photo mask (FIG. 2C) manufactured according to the present invention, where the photo mask is covered over the substrate 210, such that the UV is irradiated from a top of the photo mask 100.

In this case, the non-transmitting region 121 prevents the UV from being passed through such that a photo-cure of the solder resist below the non-transmitting region 121 is not generated (221), and the transmitting region 123 allows the UV to be transmitted at almost 100% such that a completely cured portion 222 is formed at the solder resist below transmitting region 123.

On the contrary, in a case of the semi-transmitting regions 122a and 122b, since only a portion of the UV is transmitted to reach the solder resist 220, the solder resist below the semi-transmitting regions 122a and 122b is incompletely cured (223a and 223b of FIG. 3). In this case, a light transmissivity difference is generated depending on the thickness of the non-transmitting film of the semi-transmitting regions 122a and 122b. Therefore, a degree of cure of the solder resist 220, which is a lower membranous, is varied depending on transmissivity of light transmitting each of the regions 122a and 122b.

Next, in accordance with an embodiment of the invention, when the photo mask is removed and development is then performed, a degree of removal of the solder resist is varied depending on the degree of cure of the solder resist 220, such that an opening 240 and trenches 241a and 241b for preventing an under-fill leakage are simultaneously formed on the solder resist, as shown in FIG. 3C.

As a result, the depth of the trench of preventing the under-fill leakage is varied depending on the thickness of the non-transmitting film 125 formed on the photo mask, such that the depths of the respective trenches are different or the same.

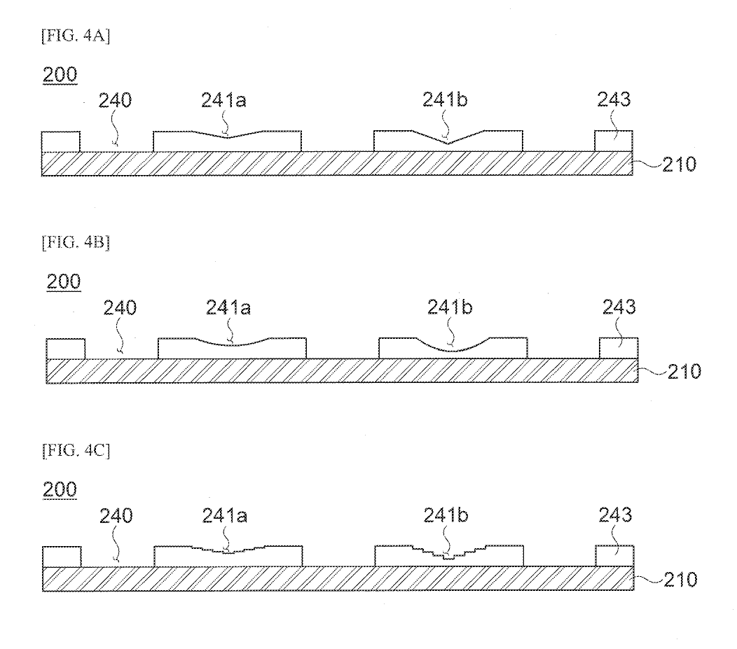

FIGS. 4A to 4C show several shapes of trenches which may be manufactured in accordance with an embodiment of the invention. A transmitted amount of UV is adjusted according to the thickness of the chrome film and the degree of cure of the solder resist, which is the lower membranous is adjusted according to the adjusted transmitted amount of UV, such that the trench for preventing the under-fill leakage having several shapes, such as the V-shape (FIG. 4A), the semi-circular shape (FIG. 4B), the step shape (FIG. 4C), and the like are formed. Of course, in addition to those mentioned above, several shapes of trenches are formed and the embodiments of the present invention is not limited to the forms shown in the drawings.

With respect to this, a form of a package will be described in more detail with reference to FIGS. 5 and 6. FIG. 5 is a cross-sectional view of a printed circuit board including the trench after an EMC molding, FIG. 6 is a cross-sectional view of the printed circuit board into which an under-fill liquid is injected when mounting a chip on the board including the trench, and at the time of injecting the under-fill liquid, the under-fill liquid flows from an injection direction (410a of FIG. 6) of the under-fill liquid to a leakage direction (410b of FIG. 6) opposite to the injection direction. Therefore, a leakage amount of an under-fill liquid is generally increased toward a leakage direction (410b of FIG. 6). Therefore, the trench 241b in the leakage direction is formed, so as to have a depth deeper than that of the trench 241a in an injection direction of the under-fill liquid, thereby making it possible to prevent the under-fill liquid from being overflowed to the outside region of the trench. Of course, the trench having the same depth in the injection direction (410a of FIG. 6) and the leakage direction (410b of FIG. 6) may be formed.

In accordance with an embodiment of the invention, the trench for preventing the under-fill leakage described above is used even in a case (FIG. 5) of preventing a sealing material from being intruded into the solder ball pad region in an epoxy mold compound (EMC) sealing process for protecting the semiconductor chip after the semiconductor chip is mounted on the substrate.

According to an exemplary embodiment of the present invention, since the additional etching process using a laser for forming the trench is not required by collectively forming the trench during exposure and development using the photo mask in the exposure process for the photo solder resist, the product time is shortened, cost is decreased, and the matching problem is not caused in the process of forming the trench, which is a subsequent process of the exposure process for the photo solder resist, thereby making it possible to improve yield.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

As used herein, terms such as “first,” “second,” and the like are arbitrarily assigned and are merely intended to differentiate between two or more components of an apparatus. It is to be understood that the words “first,” “second,” and the like serve no other purpose and are not part of the name or description of the component, nor do they necessarily define a relative location or position of the component. Furthermore, it is to be understood that the mere use of the term “first” and “second” does not require that there be any “third” component, although that possibility is contemplated under the scope of the embodiments of the present invention.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A photo mask, comprising:
a transparent base material; and
a mask pattern layer comprising a transmitting region, a non-transmitting region, and a semi-transmitting region on the transparent base material,
wherein the mask pattern layer is configured by the transmitting region in which the transparent base material is exposed, and the non-transmitting region and the semi-transmitting region in which a non-transmitting film is covered over the transparent base material, and
wherein the semi-transmitting region is formed of the non-transmitting film having a thickness thinner than the non-transmitting region.

2. The photo mask according to claim 1, wherein the transparent base material is any one of a transparent film or a transparent substrate.

3. The photo mask according to claim 1, wherein the non-transmitting region of the photo mask has a thickness of 0.1 to 0.5 μm.

4. The photo mask according to claim 1, wherein the non-transmitting region of the photo mask is a chrome film.

5. The photo mask according to claim 1, wherein the semi-transmitting region has a different light transmissivity depending on the thickness of the non-transmitting film.

6. The photo mask according to claim 1, wherein the semi-transmitting region has a light transmissivity of 40% to 90%.

7. The photo mask according to claim 1, wherein a thickness of the non-transmitting film of the semi-transmitting region is adjusted using a laser of a direct imaging method.

8. A method of manufacturing a photo mask, the method comprising:
forming a non-transmitting film on one surface of a transparent base material;
forming a transmitting region by irradiating laser on some regions of the base material having the non-transmitting film formed thereon to thereby etch the non-transmitting film; and
forming a semi-transmitting region by irradiating laser on some regions of the non-transmitting region other than the transmitting region of the transparent base material to thereby etch the non-transmitting film.

9. The method according to claim 8, wherein the etching using a laser is performed by an electron beam (E-BEAM).

10. The method according to claim 8, wherein the non-transmitting film has different thicknesses so that the semi-transmitting region has different light transmissivity at the time of etching the non-transmitting region.

11. A method of forming trenches for preventing an under-fill leakage, the method comprising:
preparing a substrate comprising a solder resist laminated thereon;
preparing the photo mask according to claim 1;
covering the photo mask over the substrate comprising the solder resist laminated thereon;
irradiating ultraviolet (UV) from a top of the photo mask;
forming an uncured region, an incomplete cured region, and a complete cured region on the solder resist by UV irradiated on a non-transmitting region, a semi-transmitting region, and a transmitting region of the photo mask; and
removing the photo mask and then developing the solder resist.

12. The method according to claim 11, wherein in the trenches for preventing the under-fill leakage, a trench in a direction opposite to an injection direction of an under-fill is formed to have a deeper depth.
